(19) United States
(12) Patent Application Publication
(10) Pub. No.: US 2016/0197056 A1
(43) Pub. Date: Jul. 7, 2016

(54) Die and Manufacturing Method for a Die

(71) Applicant: BIOTRONIK SE & Co. KG, Berlin (DE)

(72) Inventors: Siddhartha Bhowmik, Albuquerque, NM (US); Frederik Sporon-Fiedler, Corvallis, OR (US)

(21) Appl. No.: 14/911,057

(22) PCT Filed: Jul. 24, 2014
(86) PCT No.: PCT/EP2014/065913

§ 371 Date: Feb. 9, 2016

Related U.S. Application Data
(60) Provisional application No. 61/872,769, filed on Sep. 2, 2013.

(51) Int. Cl. H01L 25/065; H01L 25/00; H01L 21/78; H01L 21/304; H01L 21/768

(52) U.S. Cl. CPC H01L 25/0657; H01L 21/304; H01L 21/76898; H01L 21/78; H01L 25/50; H01L 2225/06544; H01L 2225/06593; H01L 2225/06596

(57) ABSTRACT

The present invention refers to a die (1) with an improved crack detecting structure for a predefined area of the die comprising an electrical conductive path (5,6) laid along a perimeter of the predefined area and a first bond pad (17a) at the first end of the path (5, 6) and a second bond pad (17b) at the second end of the path (5, 6), wherein the electrical conductive path (5,6) contains at least one first path section (12) disposed at the front side of the die (1) and at least one second path section (13) disposed at the back side of the die (1), wherein the at least one first path section (12) and the at least one second path section (13) are coupled by at least one through connection (14). Further, the invention refers to a respective system on package and methods for manufacturing a respective die or a respective system on package.

### CROSS-REFERENCE TO RELATED APPLICATIONS

This application is the United States national phase under 35 U.S.C. §371 of PCT International Patent Application No. PCT/EP2014/065913, filed on Jul. 24, 2014, which claims the benefit of U.S. Provisional Patent Application No. 61/872,769 filed Sep. 2, 2013, the disclosures of which are hereby incorporated by reference herein in their entireties.

### TECHNICAL FIELD

The present invention refers to a die and a system on package as well as a manufacturing method for a die and a system on package.

### BACKGROUND OF THE INVENTION

3D System-in-a package technology (in the following: system on package) involves stacking multiple semiconductor die or wafer in a vertical manner. To minimize volume, vertical stacking requires significant thinning of wafers followed by singulation for die separation, or in some instances may need singulation after wafer level stacking. Due to stress in both wafer thinning process and singulation process, small micro-cracks may be initiated which are latent defects that can cause longer term crack propagation, ultimately leading to non-functional systems on package at later stages of packaging, shipping or field use of a packaged product. In the vast majority of cases, these micro-cracks originate at the edge of the die and propagate through the die with time. Cracks can originate on both sides of the die and may propagate gradually. Testing standard functional structures do not serve as a testing for these micro-cracks.

There exist structures known to be made either by implant or metallization during front end wafer processing that would be adept at detecting early crack initiation sites on the front side of die. In addition increasing usage of Silicon on insulator wafers and die would also slow crack propagation. But a crack originating at the back which would temporarily stop at the Oxide (insulating) interface could propagate and crack the die later in the field.

Further it is known that to reduce the occurrence of micro-cracks during backgrinding, singulation or a combination of both, visual inspections may be used but is difficult or impossible to implement once a system on package has been built.

Document U.S. Pat. No. 6,649,986 B1 discloses a semiconductor device that includes structures for detecting die or dice cracks that occur in semiconductor chips when dicing the wafer during production. The known structures comprise multiple metalized pads and die or dice crack detection interconnections, both of the pads and the interconnection encircling the central region of the semiconductor device, wherein the interconnections are accommodated on the top side of the wafer as a single continuous structure for detection of cracks that occur on and extend from the top surface side of the semiconductor chip. In another embodiment the structure comprises a die crack detection diffusion layer as the die crack detection interconnection, wherein the diffusion layer is accommodated in an area under the field region in the vicinity of the boundary surface, fabricated for example by through-diffusion after doping into the desired region of the semiconductors substrate. The diffusion layer is connected to detection terminals which are situated on the top of the semiconductor device. This embodiment allows detection of die/dice cracks that occur on and extend from primarily the bottom surface side of the semiconductor chip.

Document US 2009/0201043 A1 refers to a crack sensor for semiconductor devices, wherein the crack sensor comprises a conductor structure formed in continuous line that extends along the entire perimeter region of the semiconductor device between the interior region and a scribe line region. The known sensor comprises a conductive structure with a plurality of first portions disposed in a first conductor material layer and a plurality of second portions disposed in a second conductive material layer, wherein the plurality of first portions is coupled to at least one of the plurality of second portions by means of vias in a third metallization layer.

The above mentioned concepts address specifically cracks which originate either on the front side or within the front side interconnect stackup of a semiconductor device. However, as cracks may originate on both sides of the die and may not propagate through the entire cross section, a crack detection technology is needed which addresses cracks that originate on both sides of the die which is likely to occur with significant backside processing involved in system on package technology.

At least the above problem is solved by a die with the features of claim 1 and a system on package with features of claim 5. Further, the problem is solved by a method for manufacturing a respective die and a method for manufacturing a system on package according to the features of claims 6 and 7.

In particular the inventive die has a crack detecting structure for a predefined area of the die comprising an electrical conductive path laid around a perimeter of the predefined area and a first bond pad at the first end of the path and a second bond pad at the second end of the path, wherein the electrical conductive path contains at least one first path section disposed at the front side of the die, e.g. at the top side of the wafer substrate above a dielectric layer, and at least one second path section disposed at the back side of the die, e.g. at the back side of the wafer substrate, wherein the at least one first path section and the at least one second path section are coupled by at least one through connection.

The present invention is directed toward overcoming one or more of the above-mentioned problems.

### SUMMARY OF THE INVENTION

The inventive solution with a chain structure has the advantage that it addresses defects on both sides of the die independent on the origin of the crack defect site and that it allows removal of functional parts that have nascent cracking.

When a crack propagates and reaches one of the elements of the electrical conductive path the resistance of this path is significantly increased and thereby a crack detection is provided using the first and the second bond pad.

An extension of this could be done with multiple die stacking, where this chain is connected to multiple stacked die to enable a packaged 3D system on package to be tested for cracks emanating at the edge.

In a preferred embodiment the electrical conductive path consists of a plurality of first metal sections disposed at the front side of the die and a plurality of second metal sections disposed at the back side of the die and a plurality of through connections, wherein the first metal sections and the second metal sections are accommodated in the way that the second end of one first metal section is coupled to the first end of one second metal section by one through connection and a second end of one second metal section is coupled to the first end of the next one first metal section by another through connection. Therein, the one second metal section and the next one first metal section are not coupled to the first or second bond pad.

The above explained preferred embodiment refers to a low-cost solution of the above explained invention which has advantages with regard to the manufacturing procedure.

In another embodiment at least one first path section and at least one second path section form a double path structure with an inner electrical conductive path and an outer electrical conductive path. Preferably the first end of the inner electrical conductive path is coupled to the first end of the outer electrical conductive path and a first bond pad and the second end of the inner electrical conductive path is coupled to the second end of the outer electrical conductive path and the second bond pad. Therein the inner electrical conductive path is situated at the inner side within the perimeter region if regarded in lateral direction. The outer electrical conductive path is situated at the outer side within the perimeter region if regarded in lateral direction. Each of the inner electrical conductive path and the outer electrical conductive path has the same structure as the electrical conductive path generally described above. The structure according to this embodiment is more costly but provides a higher possibility to detect cracks emanating from both sides of the die.

It is of further advantage if the through connections of the double path structure are situated in the way that they form an offset pattern so that it is possible to detect cracks in a bigger region. That means that the through connections of the inner and outer path are accommodated alternatingly.

The inventive solution further refers to a system on package comprising a plurality of dies, wherein each die comprises the above mentioned features, wherein the first bond pad of a first die is coupled to the first bond pad of an adjacent die and the second bond pad of the first die is coupled to the second bond pad of the adjacent die.

The inventive method for manufacturing a die comprises the following steps:
a. Provide a wafer substrate with an array of dies, preferably comprising a dielectric layer at the top side of the wafer substrate, wherein each die comprises a predefined area in which cracks may occur in the respective die,
b. Fabricate at least one first path section of a crack detecting structure at the top side of each die, e.g. above the dielectric layer, along a perimeter section of the predefined area of each die, preferably together with the front side circuit elements,
c. Thin/Backgrind the wafer substrate, thereby creating a thin wafer substrate with multiple die on it,
d. Create and fill through connections at each die with a suitable metal using through-die vias to enable an electrical connection to the respective adjacent first path section of each die,
e. Fabricate at least one second path section on the back side of the each die, preferably at a back side of the wafer substrate, along a perimeter section of the predefined area of each die, operable to form an electrical connection to the respective adjacent through connection in order to complete the die perimeter crack detector, that means so that an electrical conductive path is created at each die comprising the at least one first path section, the through connections and the at least one second path section,
f. Fabricate at each die a first bond pad and a second bond pad, each at one end of the electrical conductive path formed by the at least one first path section, the through connections and the at least one second path section of that die, and
g. Singulate each die from the wafer, preferably using a diamond saw or laser cutter.

Specifically, the perimeter areas of the die are more prone to cracks, so the predefined areas are preferably located on the perimeters. The integrated circuit may be manufactured in any integrated circuit process (e.g. CMOS on Si, MESFET's on GaAs, or other integrated circuit processes known to those skilled in the art).

A suitable metal for through-die vias is Copper, Gold, Aluminum, Tungsten or an alloy containing at least one of these metals.

The at least one second path section on the back side of the wafer substrate is preferably fabricated using additive/subtractive processes (e.g. lithography, etch) which are commonplace in the integrated circuit industry.

With above described inventive method it is possible to create and fill the through-die vias in step d) before or after thinning/backgrinding of the wafer substrate (step c)).

The inventive method for manufacturing a system on package comprises the following steps:
A. Fabricate a first die and at least one second die to be packaged with the method described above,
B. Fabricate for the first die and the at least one second die a first interconnect electrically coupled to the first bond pad and a second interconnect electrically coupled to the second bond pad, and
C. Build the system on package by aligning and stacking the first die and the at least one second die such that the first interconnect of the first die is electrically connected to the first interconnect of the at least one second die and the second interconnect of the first die is electrically connected to the second interconnect of the at least one second die.

The at least one first path section and the at least one second path section may be produced as metal lines, examples of which are Copper, Aluminum, Gold or an alloy thereof.

Fabrication of the at least one interconnect to allow perimeter crack detecting structures to be connected from the first die to the at least one second die may be accomplished, for example, by solder bumps or copper pillar technology.

The bonding of the die to each other can be accomplished by, for example, thermo-compression bonding.

A full and enabling disclosure of the present invention, including the best mode thereof, directed to one of ordinary skill in the art is set forth in the following specification of different embodiments. Thereby, further features and advantages are presented that are part of the present invention independently of the subject matter as defined in the claims.

Further features, aspects, objects, advantages, and possible applications of the present invention will become apparent from a study of the exemplary embodiments and examples described below, in combination with the figures, and the appended claims.

### BRIEF DESCRIPTION OF THE DRAWINGS

The specification refers to the accompanying figures showing schematically

FIG. 1 illustrates an inventive die in a top view,

FIG. 2 illustrates the inventive die of FIG. 1 in a cross section,

FIG. 3 illustrates the inventive die of FIG. 1 in a perspective view, and

FIG. 4 illustrates an inventive system on package in a perspective view.

### DETAILED DESCRIPTION OF THE INVENTION

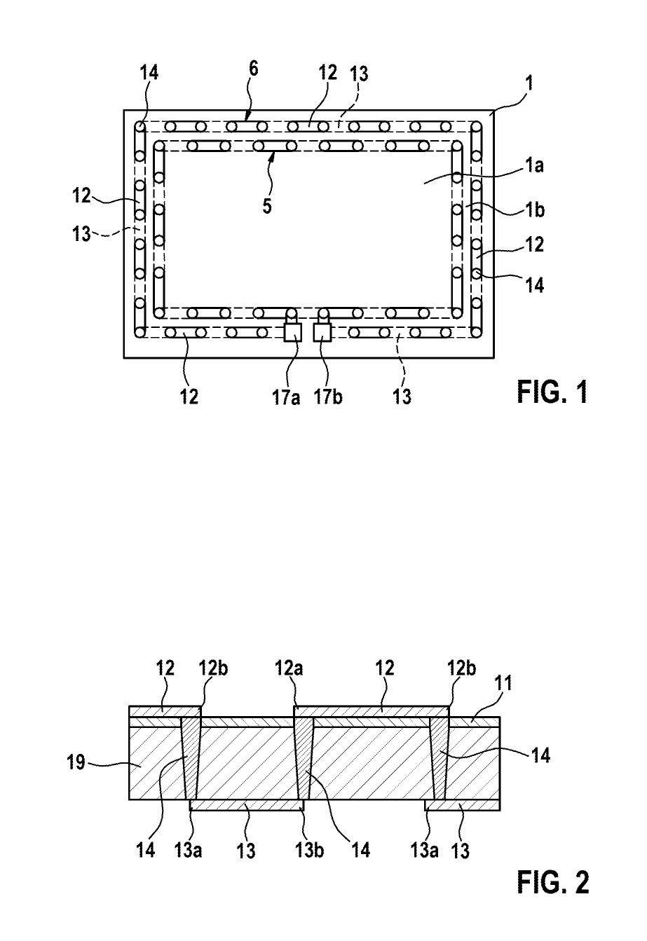

FIGS. 1 to 3 depict one embodiment of an inventive die 1 with interior region 1a for conductive structures and electrical modules and a perimeter region 1b. The die 1 further comprises a wafer substrate 19 and a dielectric layer 11 on the top side of the die substrate 19.

In the perimeter region 1b just away from the kerf resulting from the singulation process the die 1 comprises a double path structure with an inner electrical conductive path 5 and an outer electrical conductive path 6 each comprising a plurality of first metal sections 12 at the front side of the die 1 and a plurality of second metal sections 13 at the back side of the die 1. The first end of the inner electrical conductive path 5 and the first end of the outer electrical conductive path 6 is connected to a first bond pad 17a and the second end of the inner electrical conductive path 5 and the second end of the outer electrical conductive path 6 is connected to the second bond pad 17b, wherein the first bond pad 17a and the second bond pad 17b form the own bond pads of the double electrical conductive path 5, 6.

The first metal sections 12 and the second metal sections 13 of the inner electrical conductive path 5 and the outer electrical conductive path 6 are similarly coupled as shown in the cross section of FIG. 2 by through connections 14 in the way that a second end 12b of one first metal section 12 is coupled by a through connection 14 to the first end 13a of a second metal section 13 and the second end 13b of the second metal section 13 is coupled by a through connection 14 to the first end 12a of the adjacent first metal section 12 and so on.

According to the embodiment shown in FIGS. 1 to 3 the first metal sections 12 are accommodated on top of the dielectric layer 11. Further, as it is shown in particular on the left hand side and the right hand side of the die 1 depicted in FIG. 1 the through connections (through Si via metal) 14 are accommodated in an offset pattern. That means that the through connections 14 are not parallel along the horizontal direction of this Figure but shifted.

A die 1 without any cracks on the edge would have a nominal, lower, resistance measured via first and second bond pads 17a, 17b, whereas a crack on the edge of the die 1 would result in an open or higher resistance of the electrical conductive path 5 and/or 6.

In order to provide a crack detection for a system on package the bond pads 17a and 17b could be connected to the respective bond pads of the above stacked die of the system, as shown in FIG. 4. A resistance measurement for crack detection is thereby possible for the whole system on package in one single step.

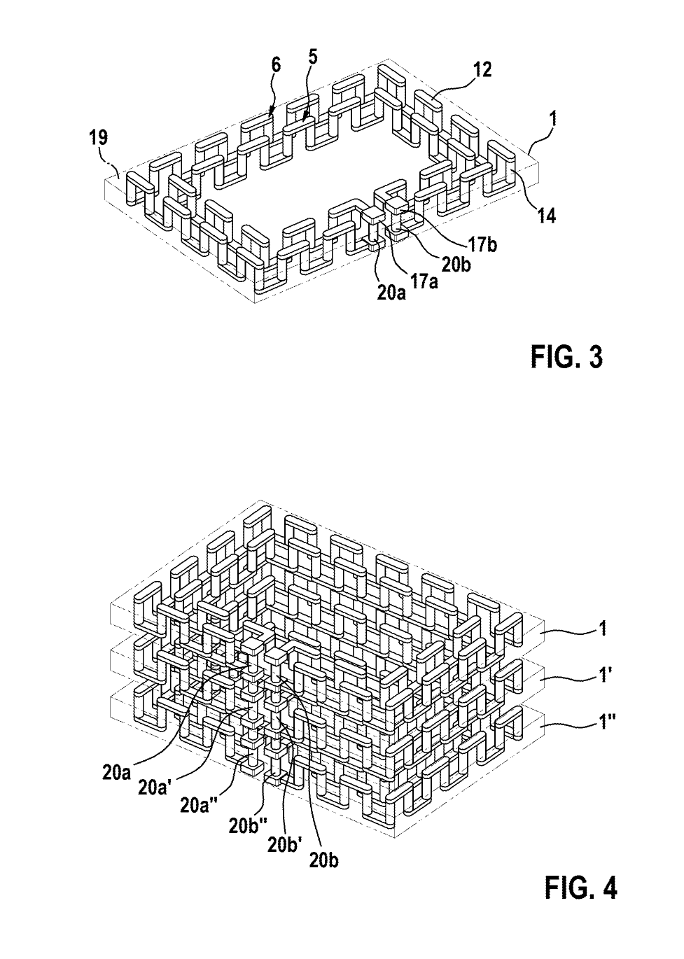

Therefore, interconnects are fabricated by techniques such as wire bonding, Copper pillars, or conductive epoxies to allow connection to the bond pads 17a, 17b such that a first interconnect 20a is electrically and mechanically connected to the first bond pad 17a and a second interconnect 20b is electrically and mechanically connected to the second bond pad 17b (see FIG. 3).

Analogous to the above description a second die 1′ and a third die 1″ is fabricated each comprising a first interconnect 20a′, 20a″ and a second interconnect 20b′, 20b″.

Now, the system on package as depicted in FIG. 4 is built by aligning and stacking the first die 1, the second die 1′ and the third die 1″. Further the interconnects are electrically connected by techniques such as thermo-compression bonding such that the first interconnect 20a of the first die 1 is connected to the first interconnect 20a′ of the second die 1′ and the first interconnect 20a′ of the second die is connected to the first interconnect 20a″ of the third die. Analogous the second interconnect 20b of the first die 1 is connected to the second interconnect 20b′ of the second die 1′ and the second interconnect 20b′ of the second die is connected to the second interconnect 20b″ of the third die. FIG. 4 shows how the lower die is connected to the top die, thereby creating a large three-dimensional daisy chain. A crack induced break in any of the links of the chain can thereby be detected using a resistance measurement between pads 20a″ and 20b″.

In a further preferred embodiment the distance of the electrical conductive path from the edge of the die is minimized to the limits of the lithography and through-via generation capability of the IC and die separation technology. For example, this distance could be minimized to ˜1 μm or less. The minimum achievable distance to the edge is determined through a tolerance analysis of the features and singulation process, followed by confirmation with process trials.

In addition, the width of the first metal sections 12, the second metal sections 13 and the through connection 14 should be minimized to allow the highest level of resistance change as soon as a micro-crack impinges on the detection line. These values can be as small as the lithographic technology will allow (30 nm as of 2013) if needed. Therein the width of the first metal section 12 and the second metal section 13 is the dimension of the respective metal section in the direction perpendicular to the top or back surface of the die 1. In contrast, the width of the through connection 14 is the dimension of this element parallel to the top or back surface of the die 1.

The proposed test structures provides improved die cracking detection and a higher level of assurance against die or system on packages with micro-cracks being accepted as good product.

It will be apparent to those skilled in the art that numerous modifications and variations of the described examples and embodiments are possible in light of the above teachings of the disclosure. The disclosed examples and embodiments are presented for purposes of illustration only. Other alternate embodiments may include some or all of the features disclosed herein. Therefore, it is the intent to cover all such modifications and alternate embodiments as may come within the true scope of this invention, which is to be given the full breadth thereof.

### LIST OF REFERENCE NUMBERS

1, 1′, 1″ first die, second die, third die
1a interior section of the first die 1
1b perimeter section of the first die 1
5 inner electrical conductive path
6 outer electrical conductive path
12 first metal section
12a first end of first metal section 12
12b second end of first metal section 12
13 second metal section
13a first end of second metal section 13
13b second end of second metal section 13
14 through connection
11 dielectric layer
17a, 17b first and second bond pad
19 wafer substrate of the first die 1
20a, 20a′, 20a″ first interconnect
20b, 20b′, 20b″ second interconnect

1. A die with a crack detecting structure for a predefined area of the die comprising an electrical conductive path laid along a perimeter of the predefined area and a first bond pad at the first end of the path and a second bond pad at the second end of the path, wherein the electrical conductive path contains at least one first path section disposed at the front side of the die and at least one second path section disposed at the back side of the die, wherein the at least one first path section and the at least one second path section are coupled by at least one through connection.

2. The die according to claim 1, wherein the electrical conductive path consists of a plurality of first metal sections disposed at the front side of the die and a plurality of second metal sections disposed at the back side of the die and a plurality of through connections, wherein the first metal sections and the second metal sections are accommodated in the way that the second end of one first metal section is coupled to the first end of one second metal section by one through connection and the second end of the one second metal section is coupled to the first end of the next one first metal section by another through connection.

3. The die according to claim 1, wherein the at least one first path section and the at least one second path section form a double path structure with an inner electrical conductive path and an outer electrical conductive path.

4. The die according to claim 3, wherein the first end of the inner electrical conductive path is coupled to the first end of the outer electrical conductive path and the first bond pad and wherein the second end of the inner electrical conductive path is coupled to the second end of the outer electrical conductive path and the second bond pad.

5. System on package comprising a plurality of dies, wherein each die comprises the features of claim 1, wherein the first bond pad of a first die is coupled to the first bond pad of an adjacent die and the second bond pad of the first die is coupled to the second bond pad of the adjacent die, each preferably via an interconnect.

6. Method for manufacturing a die comprising the following steps:
a. Provide a wafer substrate with an array of dies, wherein each die comprises a predefined area in which cracks may occur in the respective die,
b. Fabricate at least one first path section of a crack detecting structure at the top side of each die along a perimeter section of the predefined area of each die,
c. Thin/Backgrind wafer substrate,
d. Create and fill through connections at each die with a suitable metal using through-die vias to enable an electrical connection to the respective adjacent first path section of each die,
e. Fabricate at least one second path section on the back side of the each die, preferably at a back side of the wafer substrate, along a perimeter section of the predefined area of each die operable to form an electrical connection to the respective adjacent through connection,
f. Fabricate at each die a first bond pad and a second bond pad each at one end of the electrical conductive path formed by the at least one first path section, the through connections and the at least one second path section of that die, and
g. Singulate each die from the wafer, preferably using a diamond saw or laser cutter.

7. Method for manufacturing a system on package comprising the following steps:
A. Fabricate a first die and at least one second die to be packaged with the method according to claim 6,
B. Fabricate for each the first die and the at least one second die a first interconnect electrically coupled to the first bond pad and a second interconnect electrically coupled to the second bond pad, and
C. Build the system on package by aligning and stacking the first die and the at least one second die such that the first interconnect of the first die is electrically connected to the first interconnect of the at least one second die and the second interconnect of the first die is electrically connected to the second interconnect of the at least one second die.
